(19) United States
(12) Patent Application Publication
(10) Pub. No.: US 2026/0078485 A1
(43) Pub. Date: Mar. 19, 2026

(54) CLEANING A CHEMICAL VAPOR DEPOSITION CHAMBER

(71) Applicant: Lam Research Corporation, Fremont, CA (US)

(72) Inventors: Chezheng CAO, Sunnyvale, CA (US); Huifeng ZHENG, Beaverton, OR (US); Tu HONG, Tualatin, OR (US); Ivan Alexander SANCHEZ, Portland, OR (US); Chunhai JI, Portland, OR (US); Ming LI, West Linn, OR (US)

(21) Appl. No.: 19/109,548

(22) PCT Filed: Oct. 1, 2023
(86) PCT No.: PCT/US2023/075660

§ 371 Date: Mar. 6, 2025

Related U.S. Application Data
(60) Provisional application No. 63/379,421, filed on Oct. 13, 2022.

(51) Int. Cl. C23C 16/44; C23C 16/505; C23C 16/52

(52) U.S. Cl. CPC C23C 16/4405; C23C 16/505; C23C 16/52

(57) ABSTRACT

A method is provided for cleaning deposition residue from a processing chamber of a processing tool. The method comprises introducing a reactive cleaning species generated by a remote plasma into the processing chamber. An in-situ plasma is formed at a processing station within the processing chamber while introducing the reactive cleaning species generated by the remote plasma into the processing chamber.

### BACKGROUND

Semiconductor device fabrication processes involve many steps of material deposition, patterning and removal to form integrated circuits on substrates. Some steps involve the deposition of films of carbon. For example, carbon can be used as a hardmask material in patterning processes. Carbon films can be deposited by plasma-enhanced chemical vapor deposition (PECVD). PECVD involves introducing a carbon precursor into a plasma in a reduced-atmosphere environment. The plasma creates reactive species from the carbon precursor. The reactive species react to form a carbon film on a substrate in the reduced-atmosphere environment.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to cleaning a processing chamber of a processing tool. In one example method, a reactive cleaning species generated by a remote plasma is introduced into the processing chamber. An in-situ plasma is formed at a processing station within the processing chamber while introducing the reactive cleaning species generated by the remote plasma into the processing chamber.

In some such examples, generating the reactive cleaning species additionally or alternatively comprises generating reactive oxygen-containing cleaning species from a gas mixture comprising oxygen (O₂), nitrogen (N₂), and one or more inert gases.

In some such examples, the reactive oxygen-containing cleaning species additionally or alternatively comprises nitrogen oxide (NO) radicals.

In some such examples, generating the reactive cleaning species additionally or alternatively comprises generating the reactive oxygen-containing cleaning species from a gas comprising nitrous oxide (N₂O), hydrogen (H₂), or a combination thereof.

In some such examples, forming the in-situ plasma additionally or alternatively comprises applying radiofrequency (RF) power to a substrate holder within the processing chamber to thereby energize a cleaning species precursor within the processing chamber.

In some such examples, the RF power additionally or alternatively comprises a power within a range of 0.1-5.0 kW.

In some such examples, the method additionally or alternatively includes monitoring an impedance of the in-situ plasma during a deposition residue cleaning cycle.

In some such examples, the method additionally or alternatively includes detecting an endpoint of the deposition residue cleaning cycle by detecting a change in the impedance of the in-situ plasma over time, wherein the change in the impedance indicates a reduction in a quantity of a deposition residue within the processing chamber.

In some such examples, at least a portion of the in-situ plasma is additionally or alternatively located between a substrate holder of the processing chamber and a floor of the processing chamber.

In some such examples, at least a portion of the in-situ plasma is additionally or alternatively located within a gap between one or more surfaces of the processing chamber and a substrate handling component within the processing chamber.

Another example provides a processing tool. The processing tool comprises a processing chamber comprising an inlet and a processing station. The processing station comprises an in-situ plasma generator. The processing tool further comprises a remote plasma generator coupled to the inlet of the processing chamber and a controller. The controller is configured to, during a deposition residue cleaning cycle, introduce a reactive cleaning species into the processing chamber using the remote plasma generator. The controller is further configured to form an in-situ plasma at the processing station using the in-situ plasma generator of the processing station while the reactive cleaning species generated by the remote plasma generator are introduced into the processing chamber.

In some such examples, the processing tool additionally or alternatively comprises an O₂ source, a N₂ source, and an inert gas source in fluid communication with the remote plasma generator. The controller is additionally or alternatively configured to introduce O₂, N₂, and an inert gas into the remote plasma generator during the deposition residue cleaning cycle.

In some such examples, the processing tool additionally or alternatively comprises an N₂O source, an H₂ source, or a combination thereof, in fluid communication with the remote plasma generator, wherein the controller is configured to introduce N₂O and/or H₂ into the remote plasma generator during the deposition residue cleaning cycle.

In some such examples, the in-situ plasma generator additionally or alternatively comprises an RF power source configured to apply RF power to a substrate holder of the processing station.

In some such examples, the RF power source is configured to apply the RF power within a power range of 0.1-5.0 kW.

In some such examples, the controller is additionally or alternatively configured to monitor an impedance of the in-situ plasma during a deposition residue cleaning cycle.

In some such examples, the controller is additionally or alternatively configured to detect an endpoint of the deposition residue cleaning cycle by detecting a change in the impedance of the in-situ plasma over time, wherein the change in the impedance indicates a reduction in a deposition residue within the processing chamber.

Another example provides a processing tool. The processing tool comprises a processing chamber comprising a processing station. The processing station comprises an in-situ plasma generator. The processing tool further comprises a remote plasma generator and a controller. The controller is configured to, during a carbon residue cleaning cycle, introduce a reactive oxygen-containing cleaning species into the processing chamber using the remote plasma generator. The controller is further configured to form an in-situ plasma at the processing station using the in-situ plasma generator of the processing station while the reactive cleaning species generated by the remote plasma generator are introduced into the processing chamber. The controller further is configured to monitor an impedance of the in-situ plasma during the carbon residue cleaning cycle.

In some such examples, the in-situ plasma generator comprises a RF power configured to apply RF power to a substrate holder within the processing chamber to thereby energize a cleaning species precursor within the processing chamber.

In some such examples, the controller is additionally or alternatively configured to detect an endpoint of the carbon residue cleaning cycle by detecting a change in the impedance of the in-situ plasma over time, wherein the change in the impedance indicates a reduction in a carbon residue within the processing chamber.

### BRIEF DESCRIPTION OF THE DRAWINGS

FIG. 1 shows a schematic block diagram of an example processing tool.

FIG. 2 shows a schematic plan view of the processing tool of FIG. 1.

FIG. 3 shows a plot illustrating changes in impedance over time for an example processing tool.

FIG. 4 shows a flow diagram depicting an example method for cleaning deposition residue from a processing chamber of a processing tool.

FIG. 5 shows a schematic diagram of an example computing system.

### DETAILED DESCRIPTION

The term “RF” represents radiofrequency.

The term “ALD” represents atomic layer deposition.

The term “PEALD” represents plasma-enhanced atomic layer deposition.

The term “TALD” represents thermal atomic layer deposition.

The term “CVD” represents chemical vapor deposition.

The term “PECVD” represents plasma-enhanced chemical vapor deposition.

The term “TCVD” represents thermal CVD.

The term “ALD” generally represents a process in which a film is formed on a substrate in one or more individual layers by sequentially adsorbing a precursor to a substrate and then chemically transforming the adsorbed precursor to form a film layer. Examples of ALD processes comprise PEALD and TALD. PEALD and TALD respectively utilize a plasma of a reactive gas and heat to facilitate a chemical conversion of a precursor adsorbed to a substrate to a film on the substrate. The terms “growth” and “deposition”, and variants thereof, also can be used to refer to film formation.

The term “CVD” generally represents a process in which a film is formed on a substrate by a continuous flow of gas phase precursors. PECVD utilizes a plasma to form reactive species from gas phase precursors to facilitate film formation. (TCVD) utilizes heat to facilitate film formation.

The terms “clean”, “cleaning” and variants thereof generally represent removal of at least a portion of deposition residue from one or more surfaces within a processing chamber.

The term “cleaning species precursor” generally represents a material that can be introduced into a plasma to generate reactive cleaning species for cleaning deposition residue. Example cleaning species precursors for cleaning carbon residue include oxygen-containing cleaning precursors. Example oxygen-containing cleaning precursors include oxygen (O₂) and nitrous oxide (N₂O).

The term “controller” generally represents a computing system that is integrated with or otherwise in communication with a processing tool and that directs performance of a process performed by the processing tool.

The term “deposition residue” generally represents a film deposited on surfaces in a processing chamber other than a substrate. Example surfaces in a processing chamber include processing gas inlet surface, substrate holder surfaces, and chamber walls. The term “carbon residue” generally represents a deposition residue comprising carbon as a primary component.

The term “deposition residue cleaning cycle” generally represents a process cycle comprising introducing a cleaning species precursor into a remote plasma within a remote plasma generator while also forming an in-situ plasma at a processing station within a processing chamber. The term “carbon residue cleaning cycle” generally represents a deposition residue cleaning cycle in which the cleaning species precursor comprises an oxidant configured to oxidize carbon residue.

The term “endpoint” generally represents a time at which a process is finished.

The term “flattening” generally represents a decrease in a slope of a function over time.

The term “fluid communication” generally represents an ability to conduct a fluid between components.

The term “inert gas” generally represents a gas that is substantially unreactive in a processing environment. Example inert gases include nitrogen (N₂), helium (He), neon (Ne), argon (Ar), krypton (Kr), and xenon (Xe).

The term “in-situ plasma” generally represents a plasma that is formed at a processing station within a processing tool.

The term “in-situ plasma generator” generally represents a combination of components that can be used to form an in-situ plasma within a processing chamber of a processing tool. Example components include an RF power source, matching network, and a showerhead or pedestal configured as an electrode within the processing chamber.

The term “mixture” generally represents a combination of two or more substances in which the substances are chemically distinct.

The term “pedestal” generally represents a physical structure configured to hold a substrate at a processing station.

The term “plasma” generally represents a gas comprising cations and free electrons.

The term “processing chamber” generally represents an enclosure in which chemical and/or physical processes are performed on substrates. The pressure, temperature and atmospheric composition within a processing chamber can be controllable to perform the chemical and/or physical processes.

The term “processing gas outlet” generally represents a structure for injecting a gas-phase processing chemical into a processing chamber of a processing tool. The term “showerhead” generally represents a processing gas outlet comprising a plurality of holes distributed across an area. A processing gas outlet can act as an electrode in an in-situ plasma generator.

The term “processing station” generally represents a location within the processing chamber at which a substrate is positioned during substrate processing.

The term “processing tool” generally represents a machine including a processing chamber and other hardware configured to enable processing to be carried out in the processing chamber. PECVD and PEALD tools are examples of processing tools.

The term “radical” generally represents a chemical species that includes an unpaired electron.

The term “RF power source” generally represents an apparatus that outputs RF power to electrodes to generate a plasma at a processing station within a processing chamber or within a remote plasma chamber of a remote plasma generator.

The term “reactive cleaning species” generally represents one or more of an ion or a radical generated by the introduction of a cleaning species precursor to a plasma. The term “reactive oxygen-containing cleaning species” generally represents a substance that can oxidize carbon residue and that is formed by introducing an oxygen-containing cleaning species precursor into a plasma.

The term “remote plasma” generally represents a plasma used to generate reactive cleaning species at a location remote from a processing station of a processing tool.

The term “remote plasma generator” generally represents a combination of components that can be used to form a remote plasma at a location separate from a processing station of a processing chamber. A remote plasma generator includes a remote plasma chamber.

The term “remote plasma chamber” generally represents an enclosure in which a plasma is generated at a location remote from a processing station of a processing chamber. A remote plasma chamber is configured to introduce reactive species such as radicals into a processing chamber after generation. A remote plasma chamber can be configured to generate an inductively coupled plasma, a capacitively coupled plasma, or a microwave plasma. A remote plasma chamber can share a common vacuum system with a processing chamber, such that a gas introduced into the remote plasma chamber flows into the processing chamber. The remote plasma chamber can be configured to form an inductively coupled plasma, a capacitively coupled plasma, or a microwave plasma. A remote plasma generated in a remote plasma chamber can generate reactive cleaning species from a cleaning species precursor introduced into the remote plasma. A flow of an inert gas may be included with the flow of the cleaning species precursor.

The term “substrate” generally represents any object on which a film can be deposited.

The term “substrate holder” generally represents a physical structure configured to hold a substrate. A pedestal is an example of a substrate holder.

As described above, PECVD is a process that is used to deposit a material on a substrate. For example, PECVD can be used to deposit a carbon film on a substrate by introducing a carbon-containing precursor into a plasma. The plasma generates reactive carbon-containing species from the carbon-containing precursor. Reactive carbon-containing species that encounter the substrate form a carbon film on the substrate. However, deposition of the carbon film is not contained to the substrate. Instead, the carbon film is also deposited on surfaces of the processing chamber. Examples include chamber walls, exposed surfaces of a pedestal configured to hold the substrate, and surfaces of a processing gas outlet configured to dispense a processing chemical into the processing chamber. Such carbon films are referred to herein as carbon residue. Similarly, other deposition processes, including other CVD processes and ALD processes such as PEALD, also form residue in deposition chambers. Carbon residue and other residue from deposition are referred to generally herein as deposition residue. Deposition residue can act as a source of particle contamination within the processing chamber.

It can be challenging and time-consuming to clean the entire processing chamber using existing methods. For example, diffusion rates and flow distribution of reactive cleaning species within the processing chamber can result in relatively lower concentrations of the reactive cleaning species reaching some locations in the processing chamber. In addition, at least some of the reactive cleaning species can be extinguished (e.g., due to recombination or other reactions) before reaching some portions of the processing chamber.

Thus, examples are disclosed that relate to efficiently cleaning deposition residue in a processing chamber. Briefly, reactive cleaning species generated by a remote plasma are introduced into the processing chamber. As mentioned above, the reactive cleaning species may undergo recombination or other reactions in the processing chamber. Further, the remote plasma does not convert all cleaning species precursor into reactive cleaning species. Thus, some cleaning species precursor also flows into the processing chamber from the remote plasma generator. As such, an in-situ plasma is formed at a processing station within the processing tool while introducing the reactive cleaning species from the remote plasma to generate additional reactive cleaning species in the processing chamber. The additional reactive cleaning species generated by the in-situ plasma may enable reactive cleaning species to reach hard-to-clean areas of a processing tool more quickly and in relatively higher concentration than when a remote plasma alone is used. In some such examples, an impedance of the in-situ plasma is monitored to detect removal of the deposition residue from the processing chamber. This allows detection of an endpoint of a deposition residue cleaning cycle.

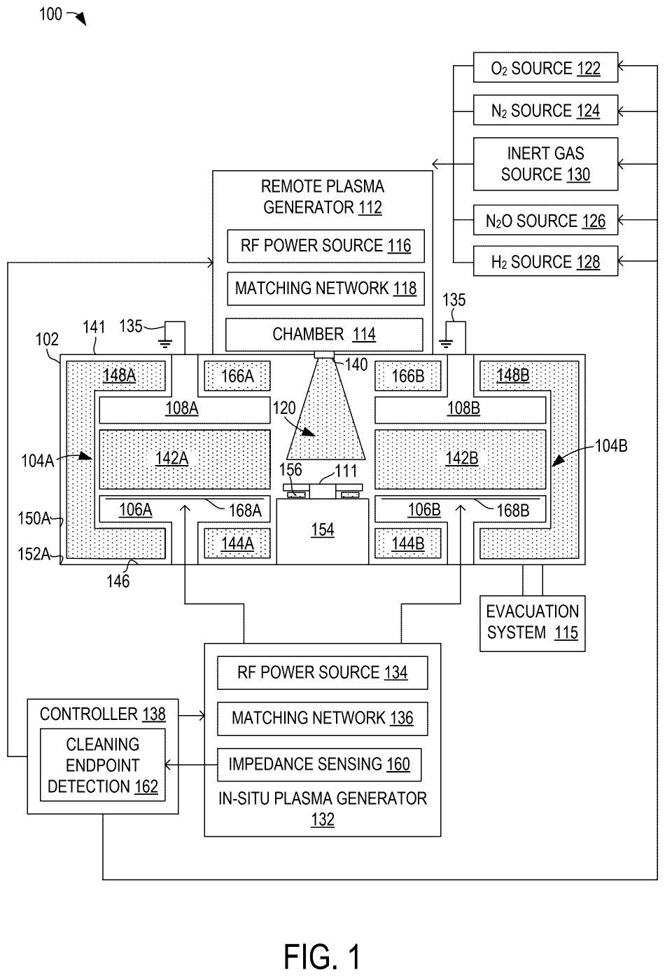

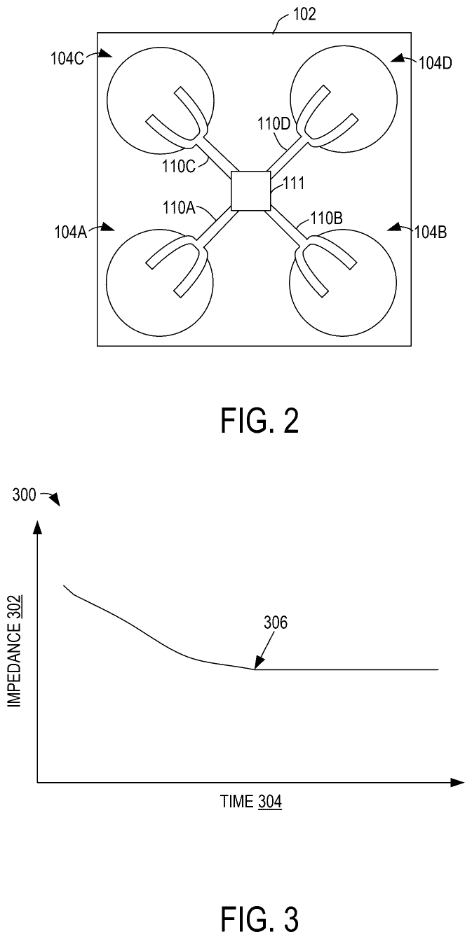

FIG. 1 shows a schematic side view of an example processing tool 100. FIG. 2 shows a schematic plan view of the processing tool 100. The processing tool 100 comprises a processing chamber 102. Referring to FIG. 2, the processing chamber 102 comprises four processing stations 104A, 104B, 104C, 104D. In other examples, a processing chamber comprises any other suitable number of processing stations, such as one, two, three, five, or more processing stations. Processing stations 104C, 104D are located behind processing stations 104A, 104B respectively in the view of FIG. 1, and thus not shown in FIG. 1. It should be appreciated that the structures of processing stations 104A, 104B described herein with regard to FIG. 1 can also be incorporated in processing stations 104C, 104D.

Continuing with FIG. 1, processing stations 104A, 104B respectively include substrate holders 106A, 106B. Processing stations 104A, 104B also respectively include processing gas outlets 108A, 108B. Each processing gas outlet 108A, 108B comprises a structure configured to dispense a gas-phase processing chemical into the processing chamber 102 toward a substrate located on a respective substrate holder 106A, 106B. In some examples, each processing gas outlet 108A, 108B comprises a showerhead configured to dispense the gas-phase processing chemical through a plurality of holes distributed across an area.

Referring again to FIG. 2, the processing chamber 102 further includes a substrate handling system comprising components including arms 110A, 110B, 110C, 110D and a hub 111. The arms 110A, 110B, 110C, 110D are not shown in FIG. 1 for clarity. The arms 110A, 110B, 110C, 110D are configured to place substrates at the processing stations 104A, 104B, 104C, 104D, respectively, to move substrates between the processing stations 104A, 104B, 104C, 104D, and/or to remove substrates from the processing chamber 102. In other examples, a substrate handling system can comprise a rotating plate.

Returning to FIG. 1, the processing tool 100 further comprises a remote plasma generator 112. The remote plasma generator 112 comprises a remote plasma chamber 114, an RF power source 116, and an impedance matching network 118. In various examples, the remote plasma generator 112 can comprise a capacitively coupled plasma generator, an inductively coupled plasma generator, or a microwave plasma generator.

During a cleaning process, a flow of one or more cleaning species precursors is introduced into a plasma in the remote plasma chamber 114 from one or more cleaning species precursor source(s), described below. Cleaning species precursors introduced into the remote plasma chamber 114 are activated by the plasma into reactive cleaning species for introduction into the processing chamber 102. Introduction of the reactive cleaning species into the chamber is shown schematically at 120. In some examples, the reactive cleaning species include reactive oxygen-containing cleaning species. Examples include oxygen (O₂) radicals and nitrogen oxide (NO) radicals. Ionic cleaning species also can be generated.

Carbon residue reacts with oxygen-containing cleaning species to form volatile carbon-oxygen compounds such as carbon dioxide (CO₂) and carbon monoxide (CO). The volatile carbon compounds are then evacuated from the processing chamber 102.

As mentioned above, the remote plasma generator 112 is in fluid communication with cleaning species precursor sources. Example cleaning species precursor sources include an O₂ source 122, a nitrogen (N₂) source 124, and a nitrous oxide (N₂O) source 126. The remote plasma generator 112 can generate reactive oxygen species such as radicals from a plasma comprising O₂ and/or N₂O. Alternatively or additionally, the remote plasma generator 112 can generate nitric oxide (NO) radicals from a plasma comprising O₂ and N₂. NO radicals can have a longer radical lifetime than reactive oxygen species formed in a plasma comprising O₂. As such, the NO radicals can be able to reach more remote areas of the processing chamber 102 and to remain active for a longer time than reactive oxygen species formed in a plasma comprising O₂.

In some examples, hydrogen (H₂) from a H₂ source 128 can be used as a cleaning species precursor. In such examples, H₂ radicals formed in the remote plasma as reactive cleaning species can react with carbon residue to form methane (CH₄) and/or other volatile hydrocarbons. H₂ also can be used to regulate an oxidative nature of oxidizing reactive cleaning species. In other examples, a reactive cleaning species and/or cleaning species precursor can additionally or alternatively comprise any other suitable substance. Other examples of suitable substances include oxidizers that do not include carbon. More specific examples include hydrogen peroxide (H₂O₂), ozone (O₃), and water vapor (H₂O).

The remote plasma generator 112 also can receive a flow of an inert gas from an inert gas source 130. Example inert gases include helium (He), neon (Ne), argon (Ar), krypton (Kr), and xenon (Xe). The inert gas can act as a diluent and/or can help to stabilize a plasma comprising the cleaning species precursor and reactive cleaning species.

In some examples, the RF power applied by RF power source 116 of the remote plasma generator 112 is in a power range of 0.1-15 kW. Generally, a relatively higher power plasma can produce a greater quantity of reactive cleaning species. The RF power source 116 can generate an RF power of any suitable frequency. In some examples, RF power having a frequency in a range of 300 kHz to 90 MHz can be generated. Examples of suitable frequencies include 400 kHz, 13.56 MHz, 27 MHz, 60 MHz, and 90 MHz.

The processing tool 100 further comprises an in-situ plasma generator 132. The in-situ plasma generator can generally refer to a plasma generator that is configured to generate an in-situ plasma within the processing chamber. The in-situ plasma generator 132 is configured to generate in-situ plasmas at processing stations 104A, 104B, 104C, 104D to facilitate depositing films on substrates in a PECVD process or a PEALD process. Example plasmas 142A, 142B are shown between the processing gas outlets 108A, 108B and substrate holders 106A, 106B of processing stations 104A, 104B, respectively. As described in more detail below, the in-situ plasma generator can be used to energize unactivated cleaning species precursors and recombined cleaning species from the remote plasma generator. In this manner, the in-situ plasma generator can generate additional reactive cleaning species. This can supplement the remote plasma generator to increase the concentration of reactive cleaning species and/or distribute the reactive cleaning species more thoroughly through the processing chamber relative to the use of the remote plasma generator alone.

The in-situ plasma generator 132 comprises an RF power source 134 and a matching network 136. The RF power source 134 is configured to apply RF power to substrate holders 106A, 106B. In this example, processing gas outlets 108A, 108B are connected to electrical ground 135. In other examples, RF power can be applied to a processing gas outlet of a processing station instead of a substrate holder. Processing gas outlets 108A, 108B and substrate holders 106A, 106B also can be considered components of the in-situ plasma generator 132. The processing gas outlet and substrate holder at each processing station, for instance, is used to form a capacitively coupled plasma by RF power applied to the substrate holder.

In some examples, the RF power generated by the in-situ plasma generator 132 is in a range of 0.1-5.0 kW. The use of an RF power in this range helps to avoid damaging a substrate holder and/or a processing gas outlet of a processing station. The RF power source 134 can generate an RF power of any suitable frequency. In some examples, RF power having a frequency in a range of 300 kHz to 90 MHz can be generated. Examples of suitable frequencies include 400 kHz, 13.56 MHz, 27 MHz, 60 MHz, and 90 MHz.

In the schematic view of FIG. 1, processing station 104A and processing station 104B are shown as receiving RF power from a common RF power source 134 and matching network 136. In other examples, each processing station can comprise a separate RF power source and matching network.

The processing tool 100 further comprises a controller 138. The controller 138 comprises a computing system that controls various controllable components of the processing tool 100. For example, the controller 138 is operative to control the remote plasma generator 112 and the in-situ plasma generator 132 to clean deposition residue from the processing chamber 102.

More particularly, the controller 138 is configured to, during a deposition residue cleaning cycle, control the remote plasma generator 112 to introduce the reactive cleaning species into the processing chamber 102. The reactive cleaning species comprise radicals that react with the deposition residue. In this manner, the reactive cleaning species can remove at least a portion of the deposition residue from one or more surfaces within the processing chamber 102. In some examples, the reactive cleaning species also can comprise ions that can react with the deposition residue.

In some examples, the controller is configured to introduce oxygen from the oxygen source 122 into the remote plasma chamber 114 at a rate in the range of 1-50 liters per minute. In some examples, the controller is configured to introduce nitrogen from the nitrogen source 124 into the remote plasma chamber 114 at a rate in the range of 0.1-1.0 liters per minute. Further, in some examples, the controller is configured to introduce inert gas from the inert gas source 130 into the remote plasma chamber at a rate in the range of 1-50 liters per minute. In other examples, any other suitable gas flows can be provided to the remote plasma chamber 114.

Reactive cleaning species 120 generated by the remote plasma are introduced into the processing chamber 102 through an inlet 140. In some examples, the inlet 140 is centered in a top plate 141 of the processing chamber 102. This enables the reactive cleaning species to be distributed more evenly through the processing chamber 102 than by introducing the remote plasma at a location that is not centered in the processing chamber. In other examples, a remote plasma generator can be configured to introduce reactive cleaning species into a processing chamber at any other suitable location. For example, each processing station can have a separate remote plasma generator.

In some examples, the processing tool 100 further comprises one or more heaters. In the depicted example, substrate holder 106A comprises a first heater 168A, and substrate holder 106B comprises a second heater 106B. Heaters 168A, 168B may be controlled to heat interior surfaces of the processing chamber 102 to temperatures within a range of 200° C.-800° C. during the cleaning of the deposition residue. Such heating can be performed using a substrate holder heater, a processing gas outlet heater, and/or any other suitable heater within the processing tool. These temperatures can facilitate oxidation of the deposition residue in the processing chamber 102. In other examples, a processing chamber alternatively or additionally may comprise other heaters. Examples include heaters incorporated in processing gas outlets 108A, 108B, and/or one or more chamber wall heaters.

In some examples, a pressure inside the processing chamber 102 is maintained by a chamber evacuation system 115 at less than 760 torr during cleaning. In more specific examples, the total pressure inside the processing chamber 102 is maintained in a range of 1-10 torr during cleaning. Such pressures can allow for a sufficient mean free path for reactive cleaning species to travel to surfaces within the chamber at a relatively greater distance from the inlet 140.

As introduced above, in some instances, reactive cleaning species generated by the remote plasma generator may not reach some portions of the processing chamber 102 or reach these portions of the processing chamber at a relatively slow rate and/or at a relatively low concentration. Accordingly, an advantage of the present disclosure is that during a remote plasma chamber cleaning process the controller 138 is further configured to control the in-situ plasma generator 132 to form an in-situ plasma at each of one or more of processing stations 104A, 104B, 104C, 104D. FIG. 1 schematically shows in-situ plasmas 142A, 142B respectively at processing stations 104A and 104B. Each in-situ plasma 142A, 142B generates additional reactive cleaning species in the processing chamber 102. For example, the additional reactive cleaning species may be generated by energizing cleaning species precursors provided in the processing chamber through the remote plasma generator 112. As mentioned above, some of the cleaning species precursors pass through the remote plasma generator 112 without being converted into reactive cleaning species. Further, reactive cleaning species may become extinguished (e.g., by recombination) within the processing chamber. Accordingly, the in-situ plasma generator may form reactive cleaning species from unactivated cleaning species precursors and/or recombined reactive cleaning species by the application of the RF power. The additional reactive cleaning species generated by the in-situ plasma(s) can reach portions of the processing chamber that can be challenging to clean using remote plasma cleaning alone. Thus, using a combination of the remote plasma and the in-situ plasma(s) can enable the processing tool to clean the processing chamber 102 in a shorter amount of time than through use of the remote plasma alone. The combination also can allow hard-to-reach areas within the processing chamber 102 to be more easily cleaned.

In-situ plasmas can form at other locations in the processing chamber 102 other than between a processing gas outlet and a substrate holder of a processing station due to the electric fields formed between the substrate holders 106A, 106B and other grounded surfaces of the processing chamber 102 than the processing gas outlets 108A, 108B. Forming plasmas at other locations can assist with cleaning hard-to-reach locations in the processing chamber 102. For example, an in-situ plasma 144A can form within a space between the substrate holder 106A and a floor 146 of the processing chamber 102 by applying RF power to the substrate holder 106A and grounding the floor 146. An in-situ plasma 144B likewise can form within a space between the substrate holder 106B and the floor 146 of the processing chamber 102 by applying RF power to the substrate holder 106B and grounding the floor. In-situ plasmas 144A and 144B can help to clean under substrate holders 106A, 106B. As another example, an in-situ plasma 148A can form adjacent to a wall location 150A of the processing chamber by applying RF power to the substrate holder 106A and grounding the wall of the processing chamber 102. This can include adjacent to a corner location 152A where the floor 146 and the wall 150 location meet. A similar in-situ plasma 148B can form adjacent to processing station 104B, as well as other processing stations. As yet another example, in-situ plasmas 166A, 166B can form within a space between the processing gas outlets 108A, 108B and the top plate 141 of the processing chamber, respectively, as a result of an electric field extending between the substrate holders 106A, 106B and the top plate 141.

As mentioned above, forming an in-situ plasma using the in-situ plasma generator can facilitate cleaning of hard-to-reach locations. For example, hub 111 and arms 110A, 110B, 110C, 110D (FIG. 2) of a wafer handling system can be supported by a base 154 and separated from the base 154 by a gap. Deposition residue within the gap can be challenging to clean, as at least a portion of base 154 is in a shadow of the hub 111 from a perspective of inlet 140. However, reactive cleaning species formed by an in-situ plasma can reach the gap between hub 111 and base 154 more easily. Further, in some examples, an in-situ plasma 156 can form between a substrate handling component, such as arms 110A, 110B, 110C, 110D and the hub 111, and one or more surfaces of the processing chamber 102, such as the base 154. Forming plasmas at these locations can generate reactive cleaning species at those locations, thereby helping to reduce a time of a cleaning process. This also can cause some ion bombardment of the surfaces in these locations, and thus etch away at least some deposition residue.

In some examples, an endpoint of a cleaning process can be estimated. In such examples, the time allotted for a processing chamber cleaning process can be overestimated to ensure a thorough cleaning is performed. Overestimating a cleaning time can result in lower throughput than where cleaning is actively monitored. As such, in some examples, the controller 138 is configured to actively monitor data regarding processing chamber conditions to detect a cleaning endpoint. For example, the controller can monitor an impedance of the in-situ plasma using an impedance sensing system 160 to detect removal of or a reduction in the deposition residue from the processing chamber 102. During a cleaning process, the presence of volatile oxidized carbon species such as CO₂ changes the impedance of the plasma. As such, the in-situ plasma generator 132 can comprise one or more sensors to implement impedance sensing system 160. As one example, the in-situ plasma generator 132 can sense a current and voltage of RF power provided to substrate holder 106A and/or substrate holder 106B using an ammeter or voltmeter, respectively. Impedance can be determined from the sensed current and voltage. As cleaning progresses, the impedance changes with changing concentration of the oxidized carbon species in the processing chamber.

When the impedance of an in-situ plasma reaches a steady-state, the controller 138 detects completion of a cleaning cycle. The resulting flattening of the change in the impedance of the in-situ plasma over time, for example, can be used for cleaning endpoint detection. For instance, FIG. 3 shows a plot 300 illustrating changes in impedance 302 over time 304 during a PECVD chamber carbon residue cleaning process utilizing a remote plasma (e.g., from the remote plasma generator 112) and an in-situ plasma (e.g., from the in-situ plasma generator 132). In the example plot 300, the measured impedance 302 of the in-situ plasma decreases as the concentration of oxidized carbon species decreases. As the slope of the impedance 302 flattens, as indicated by arrow 306, this indicates that the cleaning process is finished. In this way, the impedance reaches a steady-state value due to removal of and/or reduction in the deposition residue. As such, the flattening of the slope of the impedance can indicate completion of the deposition residue cleaning cycle. In some examples, completion of the deposition residue cleaning cycle occurs when all or substantially all of the carbon residue is removed. The term “substantially all” may generally refer to removal of sufficient deposition residue for the impedance slope to show no change over time, but where some deposition residue remains on chamber surfaces. In other examples, completion of the deposition residue cleaning cycle occurs when a predetermined amount of carbon residue is removed to prevent contamination (e.g., a sufficient amount of carbon residue to prevent particles from breaking free and contaminating a substrate within the processing chamber).

Returning to FIG. 1, data from impedance sensing system 160 serves as an input to the controller 138. In some examples, the controller 138 is configured to adjust the RF power source 116 of the remote plasma generator 112 and/or the RF power source 134 of the in-situ plasma generator 132 based upon the impedance. For example, the controller 138 can comprise code that implements a cleaning endpoint detection module 162. Using this code, the controller 138 can terminate the deposition residue cleaning cycle based upon detecting a flattening of the impedance change over time, such as that shown in FIG. 3.

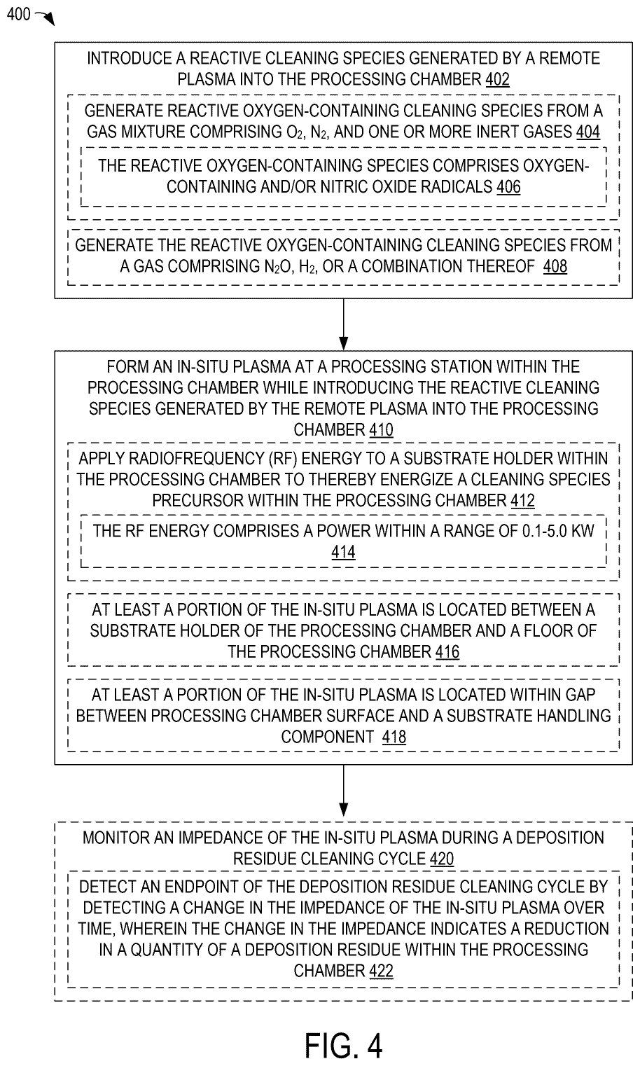

FIG. 4 shows a flow diagram depicting an example method 400 for cleaning deposition residue from a processing chamber of a processing tool. Method 400 can be used to clean processing tool 100, or any other suitable processing tool comprising a remote plasma generator and an in-situ plasma generator. Dashed outlines in FIG. 4 indicate optional steps.

At 402, the method 400 comprises introducing a reactive cleaning species generated by a remote plasma into the processing chamber. Introducing the reactive cleaning species into the processing chamber enables the reactive cleaning species to remove at least a portion of deposition residue from one or more surfaces within the processing chamber.

In some examples, at 404, generating the reactive cleaning species comprises generating reactive oxygen-containing cleaning species from a gas mixture comprising O₂, N₂ and one or more inert gases. In some examples, the oxygen-containing cleaning precursor species comprises an oxidant such as O₂, H₂O₂, H₂O_{(g)}, O₃, and/or N₂O. In some more specific examples, as indicated at 406, the reactive oxygen-containing cleaning species comprises oxygen-containing radicals and/or nitric oxide (NO) radicals generated from a gas mixture comprising O₂ and N₂. For example, the NO radicals can be formed by reactions between the O₂ and N₂ in the gas mixture of process 404. The NO radicals can have a longer radical lifetime than other radical species. As such, the NO radicals can remain active for a longer time. This can allow the NO radicals reach more remote areas of the processing chamber than other reactive cleaning species. The gas mixture further can comprise an inert gas. Examples include He, Ne, Ar, Kr, and/or Xe. The inert gas can act as a diluent and/or can help to stabilize the plasma.

In some examples, at 408, generating the reactive cleaning species comprises generating the reactive oxygen-containing cleaning species from a gas comprising N₂O, H₂, or a combination thereof. For example, the N₂O source 126 of FIG. 1 is configured to provide N₂O to the remote plasma generator 112. The N₂O can produce O₂ radicals and help to stabilize the plasma. Introducing H₂ into the remote plasma chamber can generate H₂ radicals. H₂ radicals can help to regulate the oxidative nature of the atmosphere within the processing chamber. Further, H₂ radicals formed in the remote plasma also can react with carbon residue to form volatile hydrocarbon species.

At 410, the method 400 includes forming an in-situ plasma at a processing station within the processing chamber while introducing the reactive cleaning species generated by the remote plasma into the processing chamber. For example, the in-situ plasma generator 132 of FIG. 1 is configured to generate additional reactive cleaning species in the processing chamber 102. The in-situ plasma generator can form reactive cleaning species from unreacted cleaning species precursor that flows from the remote plasma generator. The in-situ plasma generator also can form reactive cleaning species from reactive cleaning species that have been extinguished, for example, by recombination. This can result in the formation of a greater concentration of the reactive cleaning species and/or a different distribution of the reactive cleaning species in the processing chamber than by using the remote plasma generator alone. This also can help to clean hard-to-reach locations in the processing chamber

In some examples, at 412, forming the in-situ plasma comprises applying radiofrequency (RF) energy to a substrate holder within the processing chamber to thereby energize a cleaning species precursor within the processing chamber. In other examples, the RF energy can be applied to a processing gas outlet, or any other suitable electrode in a deposition chamber.

In some examples, the RF power comprises a power within a range of 0.1-5.0 KW, as indicated at 414. As described above, this power range can promote the formation of the additional reactive cleaning species while avoiding damage to components in the processing chamber.

As introduced above, when plasma is formed between the processing gas outlet and the substrate holder, plasmas also can be formed at other locations in the chamber. As indicated at 416, in some examples, a portion of the in-situ plasma can be located between a substrate holder of the processing chamber and a floor of the processing chamber. This can clean structures within a gap between the substrate holder and a floor of the processing chamber 102 more efficiently than using the reactive cleaning species produced at the remote plasma generator alone.

Likewise, at 418, in some examples, a portion of the in-situ plasma is located within a gap between one or more surfaces of the processing chamber and a substrate handling component within the processing chamber. This can clean surfaces within such a gap more efficiently than using a remote plasma alone.

As introduced above, an impedance of the in-situ RF plasma changes with changing concentration of oxidized deposition residue species in the processing chamber. Accordingly, and as indicated at 420, in some examples, the method 400 includes monitoring an impedance of the in-situ plasma during a deposition residue cleaning cycle. For example, the controller 138 of FIG. 1 is configured to monitor the impedance of the in-situ plasma to detect removal of the deposition residue.

In some more specific examples, the impedance reaches a steady state when cleaning is complete. For example, the impedance of the in-situ plasma over time can flatten at an endpoint of the cleaning process. Accordingly, at 422, in some examples, the method 400 further comprises detecting an endpoint of the deposition residue cleaning cycle by detecting a change in the impedance of the in-situ plasma over time. The change in the impedance indicates reduction in a quantity of deposition residue in the processing chamber.

In this manner, the above-described systems and methods can be used to clean deposition residue from a processing chamber of a processing tool. The combination of the remote plasma and the in-situ plasma can provide for more efficient cleaning of the processing chamber than by the remote plasma alone. Furthermore, in some examples, the impedance of the in-situ plasma indicates removal of the deposition residue from the processing chamber. This enables real-time detection of an endpoint of a deposition residue cleaning cycle. In some examples, the methods and processes described herein can be tied to a computing system of one or more computing devices. In particular, such methods and processes can be implemented as an executable computer-application program, a network-accessible computing service, an application-programming interface (API), a library, or a combination of the above and/or other compute resources.

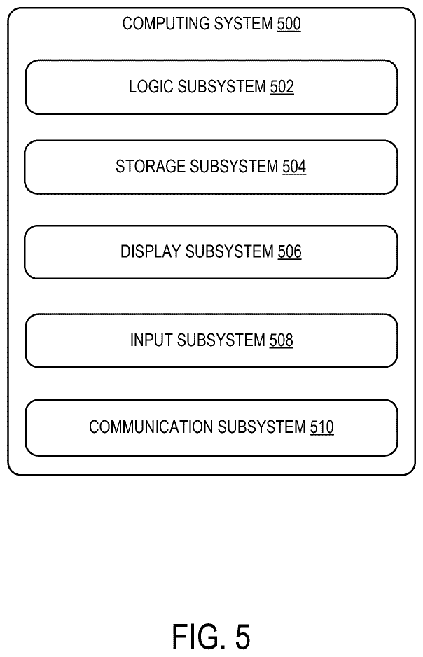

FIG. 5 schematically shows a simplified representation of a computing system 500 configured to provide any to all of the compute functionality described herein. Computing system 500 can take the form of one or more personal computers, server computers, and computers integrated with processing equipment, as examples. Controller 138 is an example of computing system 500.

Computing system 500 includes a logic subsystem 502 and a storage subsystem 504. Computing system 500 can optionally include a display subsystem 506, input subsystem 508, communication subsystem 510, and/or other subsystems not shown in FIG. 5.

Logic subsystem 502 includes one or more physical devices configured to execute instructions. For example, the logic subsystem can be configured to execute instructions that are part of one or more applications, services, programs, routines, libraries, objects, components, data structures, or other logical constructs. Such instructions can be implemented to perform a task, implement a data type, transform the state of one or more components, achieve a technical effect, or otherwise arrive at a desired result of the disclosed technology as described herein.

The logic subsystem can include one or more hardware processors configured to execute software instructions. Additionally, or alternatively, the logic subsystem can include one or more hardware or firmware devices configured to execute hardware or firmware instructions. Processors of the logic subsystem can be single-core or multi-core, and the instructions executed thereon can be configured for sequential, parallel, and/or distributed processing. Individual components of the logic subsystem optionally can be distributed among two or more separate devices, which can be remotely located and/or configured for coordinated processing. Aspects of the logic subsystem can be virtualized and executed by remotely accessible, networked computing devices configured in a cloud-computing configuration.

Storage subsystem 504 includes one or more physical devices configured to temporarily and/or permanently hold computer information such as data and instructions executable by the logic subsystem. When the storage subsystem includes two or more devices, the devices can be collocated and/or remotely located. Storage subsystem 504 can include volatile, nonvolatile, dynamic, static, read/write, read-only, random-access, sequential-access, location-addressable, file-addressable, and/or content-addressable devices. Storage subsystem 504 can include removable and/or built-in devices. When the logic subsystem executes instructions, the state of storage subsystem 504 can be transformed—e.g., to hold different data.

Storage subsystem 504 can include removable and/or built-in devices. Storage subsystem 504 can include optical memory (e.g., CD, DVD, HD-DVD, Blu-Ray Disc, etc.), semiconductor memory (e.g., RAM, EPROM, EEPROM, etc.), and/or magnetic memory, among others. Storage subsystem 504 can include volatile, nonvolatile, dynamic, static, read/write, read-only, random-access, sequential-access, location-addressable, file-addressable, and/or content-addressable devices.

Aspects of logic subsystem 502 and storage subsystem 504 can be integrated together into one or more hardware-logic components. Such hardware-logic components can include program- and application-specific integrated circuits (PASIC/ASICs), program- and application-specific standard products (PSSP/ASSPs), system-on-a-chip (SOC), and complex programmable logic devices (CPLDs), for example.

The logic subsystem and the storage subsystem can cooperate to instantiate one or more logic machines. As used herein, the term “machine” is used to collectively refer to the combination of hardware, firmware, software, instructions, and/or any other components cooperating to provide computer functionality. In other words, “machines” are never abstract ideas and always have a tangible form. A machine can be instantiated by a single computing device, or a machine can include two or more sub-components instantiated by two or more different computing devices. In some implementations a machine includes a local component (e.g., software application executed by a computer processor) cooperating with a remote component (e.g., cloud computing service provided by a network of server computers). The software and/or other instructions that give a particular machine its functionality can optionally be saved as one or more unexecuted modules on one or more suitable storage devices.

When included, display subsystem 506 can be used to present a visual representation of data held by storage subsystem 504. This visual representation can take the form of a graphical user interface (GUI). As the herein described methods and processes change the data held by the storage subsystem, and thus transform the state of the storage subsystem, the state of display subsystem 506 can likewise be transformed to visually represent changes in the underlying data. Display subsystem 506 can include one or more display devices utilizing virtually any type of technology. Such display devices can be combined with the logic subsystem and the storage subsystem in a shared enclosure, or such display devices can be peripheral display devices.

When included, input subsystem 508 can comprise or interface with one or more input devices such as a keyboard, mouse, touch screen. In some examples, the input subsystem can comprise or interface with selected natural user input (NUI) componentry. Such componentry can be integrated or peripheral, and the transduction and/or processing of input actions can be handled on- or off-board. Example NUI componentry can include a microphone for speech and/or voice recognition; and an infrared, color, stereoscopic, and/or depth camera for machine vision and/or gesture recognition.

When included, communication subsystem 510 can be configured to communicatively couple computing system 500 with one or more other computing devices. Communication subsystem 510 can include wired and/or wireless communication devices compatible with one or more different communication protocols. As non-limiting examples, the communication subsystem can be configured for communication using a wireless telephone network, or a wired or wireless local- or wide-area network. In some examples, the communication subsystem can allow computing system 500 to send and/or receive messages to and/or from other devices using a network such as the Internet.

This disclosure is presented by way of example and with reference to the associated drawing figures. Components, process steps, and other elements that can be substantially the same in one or more of the figures are identified coordinately and are described with minimal repetition. It will be noted, however, that elements identified coordinately can also differ to some degree. It will be further noted that some figures can be schematic and not drawn to scale. The various drawing scales, aspect ratios, and numbers of components shown in the figures can be purposely distorted to make certain features or relationships easier to see.

“And/or” as used herein is defined as the inclusive or V, as specified by the following truth table:

| A | B | A ∨ B |
|---|---|---|
| True | True | True |
| True | False | True |
| False | True | True |
| False | False | False |

The terminology “one or more of A or B” as used herein includes A, B, or a combination of A and B. The terminology “one or more of A, B, or C” is equivalent to A, B, and/or C. As such, “one or more of A, B, or C” as used herein includes A individually, B individually, C individually, a combination of A and B, a combination of A and C, a combination of B and C, or a combination of A, B and C.

It will be understood that the configurations and/or approaches described herein are exemplary in nature, and that these examples are not to be considered in a limiting sense, because numerous variations are possible. The specific routines or methods described herein can represent one or more of any number of strategies. As such, various acts illustrated and/or described can be performed in the sequence illustrated and/or described, in other sequences, in parallel, or omitted. Likewise, the order of the above-described processes can be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method for cleaning a processing chamber of a processing tool, the method comprising:
introducing a reactive cleaning species generated by a remote plasma into the processing chamber; and
forming an in-situ plasma at a processing station within the processing chamber while introducing the reactive cleaning species generated by the remote plasma into the processing chamber.

2. The method of claim 1, wherein generating the reactive cleaning species comprises generating reactive oxygen-containing cleaning species from a gas mixture comprising oxygen (O₂), nitrogen (N₂), and one or more inert gases.

3. The method of claim 2, wherein the reactive oxygen-containing cleaning species comprises nitrogen oxide (NO) radicals.

4. The method of claim 1, wherein generating the reactive cleaning species comprises generating the reactive oxygen-containing cleaning species from a gas comprising nitrous oxide (N₂O), hydrogen (H₂), or a combination thereof.

5. The method of claim 1, wherein forming the in-situ plasma comprises applying radiofrequency (RF) energy to a substrate holder within the processing chamber.

6. The method of claim 5, wherein the RF energy comprises a power within a range of 0.1-5.0 kW.

7. The method of claim 1, further comprising monitoring an impedance of the in-situ plasma during a deposition residue cleaning cycle.

8. The method of claim 7, further comprising detecting an endpoint of the deposition residue cleaning cycle by detecting a change in the impedance of the in-situ plasma over time, wherein the change in the impedance indicates a reduction in a quantity of a deposition residue within the processing chamber.

9. The method of claim 1, wherein at least a portion of the in-situ plasma is located between a substrate holder of the processing chamber and a floor of the processing chamber.

10. The method of claim 1, at least a portion of the in-situ plasma is located within a gap between one or more surfaces of the processing chamber and a substrate handling component within the processing chamber.

11. A processing tool, comprising:
a processing chamber comprising an inlet and a processing station, the processing station comprising an in-situ plasma generator;
a remote plasma generator coupled to the inlet of the processing chamber; and
a controller configured to, during a deposition residue cleaning cycle,
introduce a reactive cleaning species into the processing chamber using the remote plasma generator; and
form an in-situ plasma at the processing station using the in-situ plasma generator of the processing station while the reactive cleaning species generated by the remote plasma generator are introduced into the processing chamber.

12. The processing tool of claim 11, further comprising an O₂ source, a N₂ source, and an inert gas source in fluid communication with the remote plasma generator, and wherein the controller is configured to introduce O₂, N₂, and an inert gas into the remote plasma generator during the deposition residue cleaning cycle.

13. The processing tool of claim 11, further comprising an N₂O source, an H₂ source, or a combination thereof, in fluid communication with the remote plasma generator, wherein the controller is configured to introduce N₂O and/or H₂ into the remote plasma generator during the deposition residue cleaning cycle.

14. The processing tool of claim 11, wherein the in-situ plasma generator comprises a radiofrequency (RF) power source configured to apply RF power to a substrate holder of the processing station.

15. The processing tool of claim 14, wherein the RF power source is configured to apply RF power within a range of 0.1-5.0 kW.

16. The processing tool of claim 11, wherein the controller is further configured to monitor an impedance of the in-situ plasma during a deposition residue cleaning cycle.

17. The processing tool of claim 16, wherein the controller is configured to detect an endpoint of the deposition residue cleaning cycle by detecting a change in the impedance of the in-situ plasma over time, wherein the change in the impedance indicates a reduction in a deposition residue within the processing chamber.

18. A processing tool, comprising:
a processing chamber comprising a processing station, the processing station comprising an in-situ plasma generator;
a remote plasma generator; and
a controller configured to, during a carbon residue cleaning cycle,
introduce a reactive oxygen-containing cleaning species into the processing chamber using the remote plasma generator;
form an in-situ plasma at the processing station using the in-situ plasma generator of the processing station while the reactive cleaning species generated by the remote plasma generator are introduced into the processing chamber; and
monitor an impedance of the in-situ plasma during the carbon residue cleaning cycle.

19. The processing tool of claim 18, wherein the in-situ plasma generator comprises a radiofrequency (RF) power source configured to apply RF power to a substrate holder within the processing chamber to thereby energize a cleaning species precursor within the processing chamber.

20. The processing tool of claim 18, wherein the controller is further configured to detect an endpoint of the carbon residue cleaning cycle by detecting a change in the impedance of the in-situ plasma over time, wherein the change in the impedance indicates a reduction in a carbon residue within the processing chamber.
